(19) United States
(12) Patent Application Publication
(10) Pub. No.: US 2021/0273577 A1
(43) Pub. Date: Sep. 2, 2021

(54) POWER CONVERSION DEVICE

(71) Applicant: Panasonic Intellectual Property Management Co., Ltd., Osaka (JP)

(72) Inventor: Atsushi ICHINOSE, Kanagawa (JP)

(21) Appl. No.: 17/276,696

(22) PCT Filed: Aug. 22, 2019
(86) PCT No.: PCT/JP2019/032724

§ 371 Date: Mar. 16, 2021

(30) Foreign Application Priority Data
Sep. 18, 2018 (JP) 2018-173556

(51) Int. Cl. H02M 7/00; H02M 1/12; H02J 7/04; H05K 7/20

(52) U.S. Cl. CPC H02M 7/003; H02M 1/126; H02J 2207/20; H05K 7/209; H02J 2310/48; H02J 7/04

(57) ABSTRACT

Provided is a power conversion device which suppresses the propagation of noise to an AC filter with a simple configuration. The power conversion device, which converts AC power into DC power, comprises: a power conversion unit; an AC filter; and a conductive isolation member that isolates the AC filter and the power conversion unit from each other. The isolation member has: a first surface that forms at least a part of a first predetermined surface in a storage unit for storing the power conversion unit and covers at least a part of the first predetermined surface side of the power conversion unit; a second surface that covers at least a part of one surface of the AC filter disposed on an outer side of the storage unit; and third surfaces that connect the first surface and the second surface, wherein the first surface, the second surface, and the third surfaces are integrally formed so as to be conductive.

### TECHNICAL FIELD

The present disclosure relates to a power conversion apparatus.

### BACKGROUND ART

In a power conversion apparatus (e.g., an in-vehicle charger), an AC filter is provided at an input part for the purpose of preventing propagation of noise generated in the apparatus to an external AC power source apparatus connected thereto during battery charging. However, when noise from another block such as a power conversion part in the power conversion apparatus propagates to a part between the external AC power source and the AC filter, or a part between components of the AC filter or the like, the operational effect of the AC filter cannot be sufficiently provided, and the noise may propagate to the external AC power source. As such, in the power conversion apparatus, it is necessary to provide a configuration in which the AC filter is not influenced by the noise of another block.

As examples of such a configuration, a configuration in which an AC filter and a power conversion part are disposed in respective separate housings, and the like are known. In addition, PTL 1 discloses a configuration in which a partition configured to separate the AC filter and the power conversion part from each other is provided in the housing.

### CITATION LIST

### Patent Literature

### PTL 1

### Japanese Patent Application Laid-Open No. 2014-99998

### SUMMARY OF INVENTION

### Technical Problem

However, in the case where the AC filter and the power conversion part are disposed in respective separate housings, it is necessary to provide a plurality of housings, and consequently the size of the apparatus increases. In addition, in a configuration of only providing a partition as in the configuration disclosed in PTL 1, noise entered through a gap between components such as a cover may propagate to the AC filter. For example, if a conductive elastic body (such as a leaf spring, conductive cloth, and conductive rubber) is disposed to fill the above-mentioned gap for the purpose of preventing the above-described situation, it is necessary to provide the space for disposing the elastic body, and consequently the apparatus is complicated and upsized.

An object of the present disclosure is to provide a power conversion apparatus that can suppress propagation of noise to an AC filter with a simple configuration.

### Solution to Problem

A power conversion apparatus according to the present disclosure is configured to perform power conversion of AC power supplied from an AC power source into DC power, the power conversion apparatus including a power conversion part configured to perform power conversion through switching of a switching device; an AC filter provided on a power line between the AC power source and the power conversion part; and an isolation member configured to isolate the AC filter and the power conversion part from each other, the isolation member being conductive. The isolation member includes a first surface that constitutes at least a part of a first predetermined surface of a housing part configured to house the power conversion part, the first surface being configured to cover at least a part of the power conversion part on a first predetermined surface side, a second surface configured to cover at least a part of one surface of the AC filter disposed outside the housing part, and a third surface configured to connect the first surface and the second surface. The first surface, the second surface and the third surface are integrally molded with each other so as to be conductive.

### Advantageous Effects of Invention

According to the present disclosure, propagation of noise to an AC filter can be suppressed with a simple configuration.

### BRIEF DESCRIPTION OF DRAWINGS

FIG. 1 is a block diagram illustrating a power conversion apparatus according to an embodiment of the present disclosure;

FIG. 2 is a perspective view of an external appearance of the power conversion apparatus according to the present embodiment;

FIG. 3 is a top view of the power conversion apparatus according to the present embodiment;

FIG. 4 is a sectional view of the power conversion apparatus taken along a line extending in a front-rear direction in FIG. 3;

FIG. 5 is a sectional view of the power conversion apparatus taken along a line extending in the front-rear direction in FIG. 3;

FIG. 6 is a sectional view of the power conversion apparatus taken along a line extending in the front-rear direction in FIG. 3;

FIG. 7 is a sectional view of the power conversion apparatus taken along a line extending in a horizontal direction in FIG. 3;

FIG. 8 is a sectional view of the power conversion apparatus taken along a line extending in the horizontal direction in FIG. 3;

FIG. 9 is a sectional view of a power conversion apparatus according to a first modification taken along a line extending in the horizontal direction;

FIG. 10 is a sectional view of a power conversion apparatus according to a second modification taken along a line extending in the horizontal direction;

FIG. 11 is a sectional view of a power conversion apparatus according to a third modification taken along a line extending in the horizontal direction;

FIG. 12 is a sectional view of a power conversion apparatus according to a fourth modification taken along a line extending in the horizontal direction;

FIG. 13 is a top view of a power conversion apparatus according to a fifth modification; and

FIG. 14 is a top view of a power conversion apparatus according to a sixth modification.

### DESCRIPTION OF EMBODIMENTS

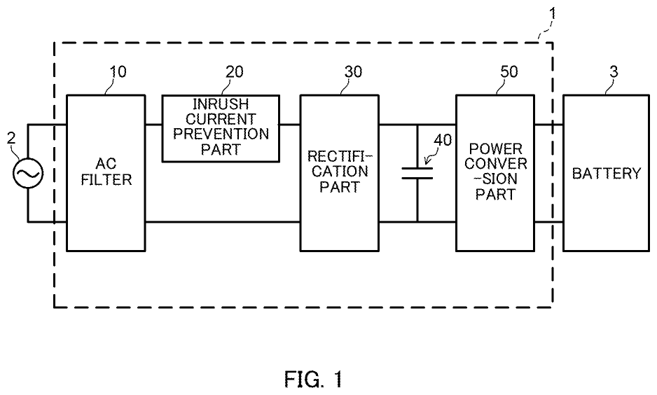

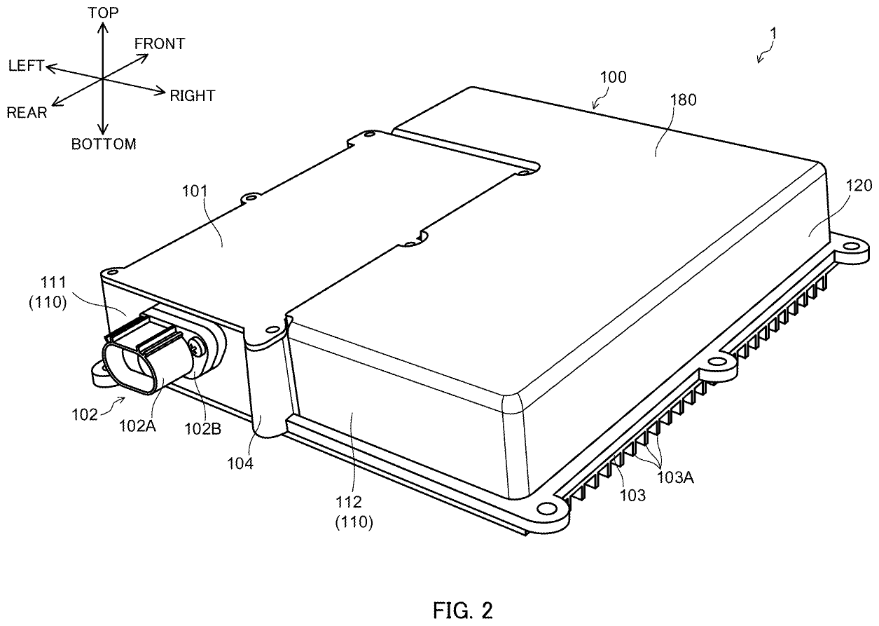

An embodiment of the present disclosure will be elaborated below with reference to the drawings. FIG. 1 is a block diagram illustrating power conversion apparatus 1 according to the embodiment of the present disclosure. FIG. 2 is a perspective view illustrating an external appearance of power conversion apparatus 1 according to the present embodiment.

As illustrated in FIG. 1, power conversion apparatus 1 is a charger connected to external AC power source 2 outside the vehicle and configured to convert AC power supplied from external AC power source 2 into DC power to charge battery 3. Battery 3 is a battery mounted in a vehicle such as an electric vehicle and a hybrid car, for example.

As illustrated in FIG. 1 and FIG. 2, power conversion apparatus 1 includes AC filter 10, inrush current prevention part 20, rectification part 30, capacitor 40, power conversion part 50, housing 100 as an example of an isolation member, cover 101, input part 102, and cooling part 103.

As illustrated in FIG. 1, AC filter 10 is provided on a power line between external AC power source 2 and power conversion part 50 (in FIG. 1, between external AC power source 2 and inrush current prevention part 20).

AC filter 10 is composed of a member such as a capacitor and a reactor, and plays a role in removing noise to prevent outflow of noise superimposed on the power line to external AC power source 2. In addition, AC filter 10 plays a secondary role in removing noise superimposed on AC power input from external AC power source 2.

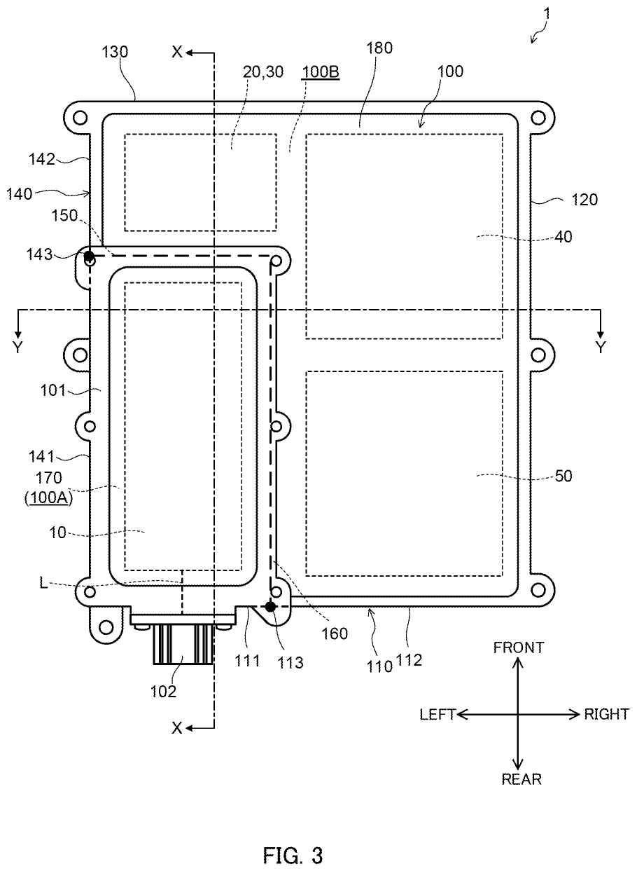

Here, the noise generated by a switching operation or the like of a switching device of power conversion part 50 described later includes electromagnetic noise (radiation noise) that propagates through the space. If the electromagnetic noise affects a part (e.g., electrical wiring L described later (see FIG. 3)) between the external AC power source 2 and AC filter 10, the noise may flow out to external AC power source 2.

In view of this, in the present embodiment, the region where apparatuses that generate electromagnetic noise (e.g., power conversion part 50) is housed and the region where AC filter 10 is housed are formed with a conductive housing (wall) with no gaps, and thus propagation of electromagnetic noise to the region where AC filter 10 is housed is suppressed.

Inrush current prevention part 20 is a circuit for preventing an inrush current, and is provided between AC filter 10 and rectification part 30. At the start of operation of power conversion apparatus 1, no electric charge is charged to capacitor 40, and therefore if DC power is output from rectification part 30, an excessive current (inrush current) may flow. However, with inrush current prevention part 20 connected to the preceding stage of rectification part 30, the influence of an excessive inrush current at the start of operation of power conversion apparatus 1 can be prevented.

Rectification part 30 includes a diode bridge circuit composed of four diodes, fully rectifies AC power output from external AC power source 2 to convert it into DC power, and outputs it to power conversion part 50, for example.

Capacitor 40 is connected between rectification part 30 and power conversion part 50, and smoothes the output of rectification part 30. In this manner, a ripple in the output of rectification part 30 can be reduced.

Power conversion part 50 includes a power factor improvement circuit and a DC/DC conversion circuit. The power factor improvement circuit improves the power factor of DC power input from rectification part 30. The DC/DC conversion circuit includes a switching device, and converts the DC power output from the power factor improvement circuit into DC power capable of charging battery 3 through switching of the switching device. When the DC power thus converted by power conversion part 50 is output to battery 3, battery 3 is charged.

The above-described AC filter 10, inrush current prevention part 20, rectification part 30, capacitor 40 and power conversion part 50 are housed inside housing 100, cover 101 and cooling part 103 as illustrated in FIG. 2 and FIG. 3.

Housing 100 is composed of conductive metal, and includes rear side wall 110, right side wall 120, front side wall 130, left side wall 140, first isolation wall 150, second isolation wall 160, bottom wall 170, and top wall 180. Housing 100 is integrally formed by die-casting, for example. Therefore, rear side wall 110, right side wall 120, front side wall 130, left side wall 140, first isolation wall 150, second isolation wall 160, bottom wall 170, and top wall 180 are integrally molded with each other so as to be conductive.

Rear side wall 110, right side wall 120, front side wall 130 and left side wall 140 are vertically extending walls, and constitute four external walls of housing 100. With rear side wall 110, right side wall 120, front side wall 130 and left side wall 140, housing 100 has a quadrangular shape in top view.

First isolation wall 150 is a wall that extends rightward from portion 143 on the front side relative to a center portion of left side wall 140 in the front-rear direction, and is connected to second isolation wall 160 described later. Note that in the following description, a portion on the rear side of portion 143 of left side wall 140 is referred to as rear side portion 141 of left side wall 140, and a portion on the front side of portion 143 is referred to as front side portion 142 of left side wall 140.

Second isolation wall 160 is a wall that extends upward from portion 113 on the left side relative to a center portion of rear side wall 110 in the horizontal direction and is connected to first isolation wall 150. Note that in the following description, a portion on the left side of portion 113 of rear side wall 110 is referred to as left side portion 111 of rear side wall 110, and a portion on the right side of portion 113 is referred to as right side portion 112 of rear side wall 110. Details of the structures of first isolation wall 150 and second isolation wall 160 are described later.

Bottom wall 170 is a bottom side wall of housing 100, and is connected to the lower end portion of each of left side portion 111 of rear side wall 110, rear side portion 141 of left side wall 140, first isolation wall 150, and second isolation wall 160. That is, bottom wall 170 constitutes a bottom side wall of first region 100A surrounded by left side portion 111 of rear side wall 110, rear side portion 141 of left side wall 140, first isolation wall 150, and second isolation wall 160.

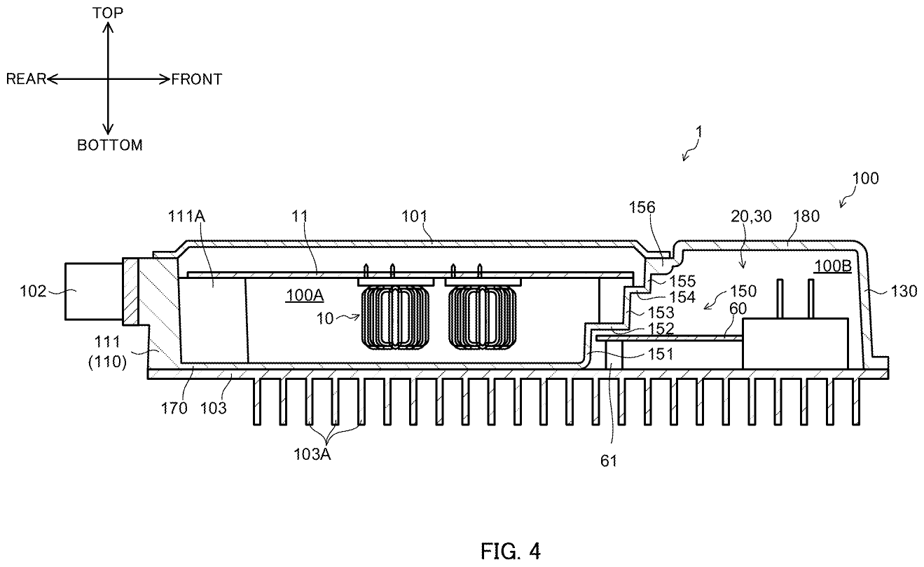

In first region 100A, AC filter 10 and substrate 11 for AC filter 10 (see FIG. 4, etc.) are disposed. Thus, bottom wall 170 covers the bottom surface (one surface) of AC filter 10. Bottom wall 170 corresponds to “second surface” of the present disclosure.

Top wall 180 is connected to the upper end portion of each of right side portion 112 of rear side wall 110, right side wall 120, front side wall 130, front side portion 142 of left side wall 140, first isolation wall 150, and second isolation wall 160. That is, top wall 180 constitutes a top side wall (a first predetermined surface) of second region 100B surrounded by right side portion 112 of rear side wall 110, right side wall 120, front side wall 130, front side portion 142 of left side wall 140, first isolation wall 150, and second isolation wall 160.

In second region 100B, inrush current prevention part 20, rectification part 30, capacitor 40 and power conversion part 50, and circuit board 60 for connecting each part (see FIG. 4, etc.) are disposed. Thus, top wall 180 covers inrush current prevention part 20, rectification part 30, capacitor 40 and power conversion part 50. Top wall 180 corresponds to “first surface” of the present disclosure. Second region 100B corresponds to “housing part” of the present disclosure.

Cover 101 is a quadrangular cover that covers first region 100A, and is composed of a conductive metal. Cover 101 is formed such that it can be disposed at the upper end portion of each of left side portion 111 of rear side wall 110, rear side portion 141 of left side wall 140, first isolation wall 150, and second isolation wall 160.

As described above, top wall 180 is located only in second region 100B, and thus the portion corresponding to first region 100A in housing 100 is open toward the top side. As such, cover 101 is disposed to cover the opening of first region 100A.

Screw holes are formed in corner portions and the like of cover 101. In the present embodiment, a total of six screw holes are formed in cover 101 at the four corners, a center portion of the left side, and a center portion of the right side. Note that the number of screw holes is not limited as long as cover 101 can be fixed to housing 100.

Fastening parts 104 for screw-fixing cover 101 are formed at positions corresponding to the screw holes in rear side wall 110, left side wall 140, first isolation wall 150 and second isolation wall 160 (see, for example, FIG. 2). Screws are inserted to the screw holes and fixed to fastening parts 104, and thus cover 101 is fixed to housing 100. In this manner, together with top wall 180, cover 101 constitutes the top side wall of power conversion apparatus 1.

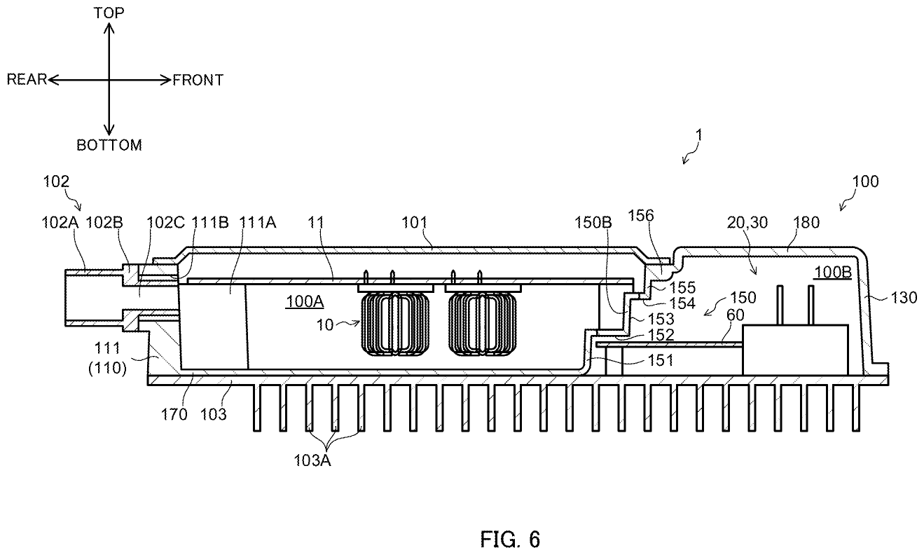

Input part 102 is a connector for inputting AC power from external AC power source 2, and is fixed to left side portion 111 of rear side wall 110. Left side portion 111 of rear side wall 110 covers the rear side (a surface different from the bottom surface) of the above-described first region 100A. Input part 102 includes first part 102A, second part 102B, and third part 102C (see FIG. 6). Left side portion 111 of rear side wall 110 corresponds to “fourth surface” of the present disclosure.

First part 102A is a part connected to external AC power source 2. Second part 102B is a part fixed to left side portion 111 of rear side wall 110, and is provided at the base end of first part 102A. Second part 102B extends to the left and right sides of first part 102A.

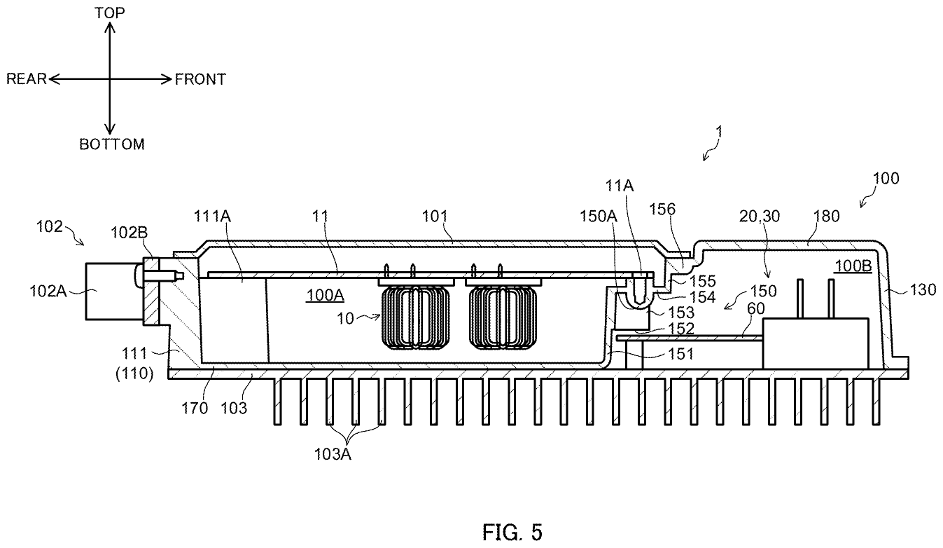

In second part 102B, screw holes are formed in the portions extending to left and right sides of first part 102A. In addition, a screw hole is also formed in the portion corresponding to the screw hole in left side portion 111 of rear side wall 110 (see FIG. 5). A screw is inserted to each screw hole, and input part 102 is fixed to housing 100.

In addition, an output part not illustrated is provided in right side portion 112 of rear side wall 110. Right side portion 112 of rear side wall 110 constitutes the rear side wall (a second predetermined surface different from the first predetermined surface) of second region 100B, and therefore when the output part is disposed in right side portion 112 of rear side wall 110, the output of power conversion part 50 is output to battery 3 and the like.

As illustrated in FIG. 6, third part 102C extends from second part 102B toward the inside of housing 100. In addition, hole 111B is formed in left side portion 111 of rear side wall 110, and third part 102C is inserted to hole 111B. With electrical wiring L (see FIG. 3) as an example of the connecting part or the like, third part 102C is connected to substrate 11 for AC filter 10. Note that input part 102 and AC filter 10 may be connected to each other with a member other than electricity line L.

As illustrated in FIG. 2, cooling part 103 is a part that cools each circuit block of power conversion apparatus 1, and includes a plurality of fins 103A protruding to the bottom side. In addition, cooling part 103 constitutes the bottom side wall of power conversion apparatus 1. More specifically, in first region 100A of housing 100, bottom wall 170 is in contact with cooling part 103 as illustrated in FIG. 4. In second region 100B, each circuit block is directly disposed at cooling part 103. Note that FIG. 4 is a sectional view taken along line X-X of FIG. 3.

Fin 103A of cooling part 103 makes contact with air, and heat generated at each circuit block in second region 100B or the like is radiated, and thus, power conversion apparatus 1 is cooled. In addition, fin 103A of cooling part 103 makes contact with air, and heat generated at AC filter 10 in first region 100A is radiated through bottom wall 170, and thus, power conversion apparatus 1 is cooled.

Next, details of a structure of first isolation wall 150 are described.

First isolation wall 150 is a wall that isolates first region 100A and second region 100B from each other in the front-rear direction. First isolation wall 150 includes first wall part 151, second wall part 152, third wall part 153, fourth wall part 154, fifth wall part 155, and sixth wall part 156.

First wall part 151 extends upward from the front end portion of bottom wall 170. Second wall part 152 extends forward from the upper end portion of first wall part 151. Third wall part 153 extends upward from the front end portion of second wall part 152.

Fourth wall part 154 extends forward from the upper end portion of third wall part 153. Fifth wall part 155 extends upward from the front end portion of fourth wall part 154. Sixth wall part 156 extends forward from the upper end portion of fifth wall part 155, and is connected to top wall 180 of housing 100. In addition, cover 101 fixed to housing 100 is placed on sixth wall part 156.

In this manner, first isolation wall 150 connects bottom wall 170 and top wall 180, and thus no gap is formed between first region 100A and second region 100B in the front-rear direction. Thus, noise generated in the circuit block of second region 100B less propagates to AC filter 10 in first region 100A. First isolation wall 150 corresponds to “third surface” of the present disclosure.

In addition, first wall part 151 is located on the rear side relative to third wall part 153 and fifth wall part 155. That is, the lower portion of first isolation wall 150 protrudes to the first region 100A side than the upper part. Accordingly, the space for disposing the circuit block, the components and the like is increased in second region 100B by the protrusion of lower portion of first isolation wall 150, and thus the dead space of first region 100A can be effectively utilized. In the example illustrated in FIG. 4, circuit board 60 and fixing part 61 for fixing circuit board 60 are disposed in the space.

In addition, as illustrated in FIG. 5, in substrate 11 for AC filter 10, screw hole 11A for insertion of a screw is formed at a predetermined position. At a position corresponding to the screw hole in first isolation wall 150, fixing part 150A is formed. Note that FIG. 5 illustrates a sectional view at a position slightly shifted to the right side than line X-X of FIG. 3.

A portion corresponding to fixing part 150A in first isolation wall 150 is composed of first wall part 151, fourth wall part 154, fifth wall part 155 and sixth wall part 156. The upper end portion of first wall part 151 and the rear end portion of fourth wall part 154 are directly connected to each other, and fixing part 150A is formed in fourth wall part 154.

In addition, at a position corresponding to the screw hole in left side portion 111 of rear side wall 110, fixing part 111A protruding forward is provided. At a position corresponding to the screw hole in fixing part 111A, a hole for insertion of a screw is formed. In this manner, substrate 11 is fixed inside first region 100A.

In addition, as illustrated in FIG. 6, wiring hole 150B for insertion of a wiring is formed in a portion of first isolation wall 150. More specifically, wiring hole 150B is formed across second wall part 152, third wall part 153 and fourth wall part 154 in first isolation wall 150. Note that FIG. 6 illustrates a sectional view at a position slightly shifted to the left side than line X-X of FIG. 3.

By passing a wiring through wiring hole 150B, substrate 11 and circuit board 60 are connected to each other. That is, AC filter 10 and each circuit in second region 100B are connected to each other. Note that from a view point of suppressing noise propagation, it is preferable to make wiring hole 150B as small as possible.

Next, details of a structure of second isolation wall 160 are described.

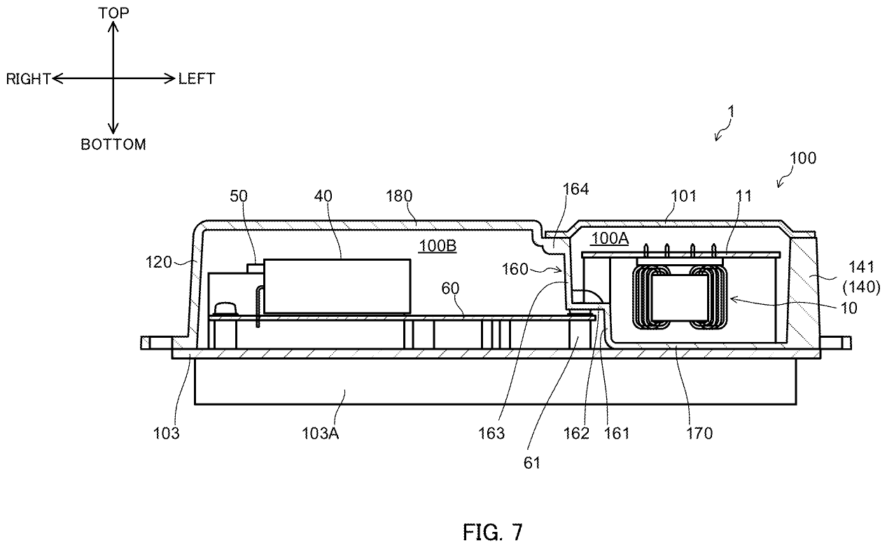

As illustrated in FIG. 7, second isolation wall 160 is a wall that isolates first region 100A and second region 100B from each other in the horizontal direction. Second isolation wall 160 includes seventh wall part 161, eighth wall part 162, ninth wall part 163, and tenth wall part 164. Note that FIG. 7 is a sectional view taken along line Y-Y of FIG. 3.

Seventh wall part 161 extends upward from the right end portion of bottom wall 170. Eighth wall part 162 extends rightward from the upper end portion of seventh wall part 161.

Ninth wall part 163 extends upward from the right end portion of eighth wall part 162. Tenth wall part 164 extends rightward from the upper end portion of ninth wall part 163, and is connected to top wall 180 of housing 100. In addition, cover 101 fixed to housing 100 is placed on tenth wall part 164.

In this manner, second isolation wall 160 connects bottom wall 170 and top wall 180, and therefore no gap is formed between first region 100A and second region 100B in the horizontal direction. Thus, noise generated in the circuit block of second region 100B less propagates to AC filter 10 in first region 100A. Second isolation wall 160 corresponds to “third surface” of the present disclosure.

In addition, seventh wall part 161 is located on the left side relative to ninth wall part 163. That is, the lower portion of second isolation wall 160 protrudes to the first region 100A side than the upper part. Accordingly, the space for disposing the circuit block, the components and the like in second region 100B is increased by the protrusion of the lower portion of second isolation wall 160, and thus the dead space of second region 100B can be effectively utilized. In the example illustrated in FIG. 7, circuit board 60 and fixing part 61 for fixing circuit board 60 are disposed in the space.

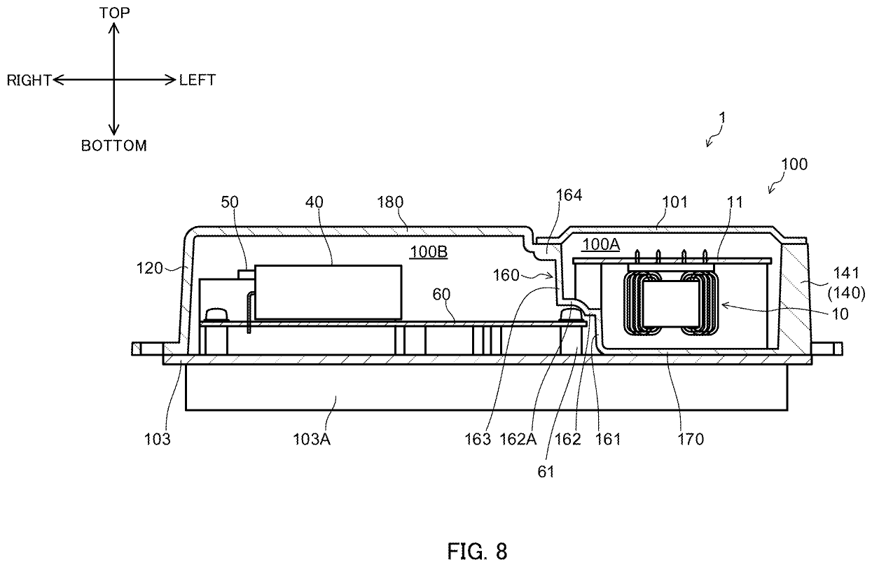

In addition, as illustrated in FIG. 8, recess 162A concaved upward is formed in the bottom surface of eighth wall part 162. A screw for fixing circuit board 60 is located at recess 162A. That is, with recess 162A formed in this manner, the component and the like to be disposed in second region 100B can be efficiently disposed by utilizing the dead space of first region 100A. Note that FIG. 8 illustrates a sectional view at a position slightly shifted to the rear side than line Y-Y of FIG. 3.

According to the present embodiment having the above-mentioned configuration, with first isolation wall 150 and second isolation wall 160, AC filter 10 is disposed completely outside second region 100B where power conversion part 50 and the like are disposed. Further, since first isolation wall 150 and second isolation wall 160 are molded integrally with top wall 180 and bottom wall 170, no gap is formed between first region 100A and second region 100B. Thus, propagation of noise generated in the circuit block of second region 100B to AC filter 10 in first region 100A can be suppressed.

Incidentally, in the case where the isolation wall is provided separately from housing 100, a gap is easily formed in components such as the cover and the isolation wall, and noise may enter from the gap and propagate to AC filter 10. If a conductive elastic body is disposed to fill that gap for the purpose of preventing the above-mentioned a situation, the space for disposing the elastic body is required and the apparatus is complicated and upsized, for example.

In the present embodiment, since first isolation wall 150 and second isolation wall 160 are molded integrally with top wall 180 and bottom wall 170, the above-mentioned gap is not formed. Therefore, the space for disposing the component for filling the gap is not required. That is, in the present embodiment, propagation of noise to AC filter 10 can be suppressed with a simple configuration.

In addition, since second isolation member 160 is integrally molded also with rear side wall 110, no gap is formed between second isolation member 160 and rear side wall 110. As a result, propagation of noise generated in the circuit block of second region 100B to AC filter 10 in first region 100A can be suppressed.

In addition, since input part 102 is disposed at left side portion 111 of rear side wall 110, input part 102, AC filter 10 and electricity line L are disposed along second isolation wall 160. In this manner, second isolation wall 160 completely isolates input part 102, AC filter 10 and electricity line L from power conversion part 50. As a result, propagation of noise generated in power conversion part 50 to AC filter 10 can be further suppressed.

In addition, since first isolation wall 150 is integrally molded also with left side wall 140, no gap is formed between first isolation wall 150 and left side wall 140. As a result, propagation of noise generated in the circuit block of second region 100B to AC filter 10 in first region 100A can be suppressed.

In addition, since first isolation wall 150 and second isolation wall 160 have portions protruding to the first region 100A side as the region on the AC filter 10 side, the components in second region 100B can be disposed by effectively utilizing the dead space of first region 100A side. As a result, the apparatus can be downsized in its entirety.

In addition, since power conversion apparatus 1 includes cooling part 103, the interior of housing 100 can be efficiently cooled. In particular, since cooling part 103 constitutes the bottom side wall of second region 100B where power conversion part 50 is disposed, power conversion part 50 and the like can make direct contact with cooling part 103. Thus, power conversion part 50 that tends to generate heat can be efficiently cooled.

Note that in the present embodiment, in housing 100, bottom wall 170, first isolation wall 150, second isolation wall 160 and top wall 180, and rear side wall 110, right side wall 120, front side wall 130 and left side wall 140 (hereinafter referred to as simply “each side wall”) are connected to each other, but the present disclosure is not limited to this.

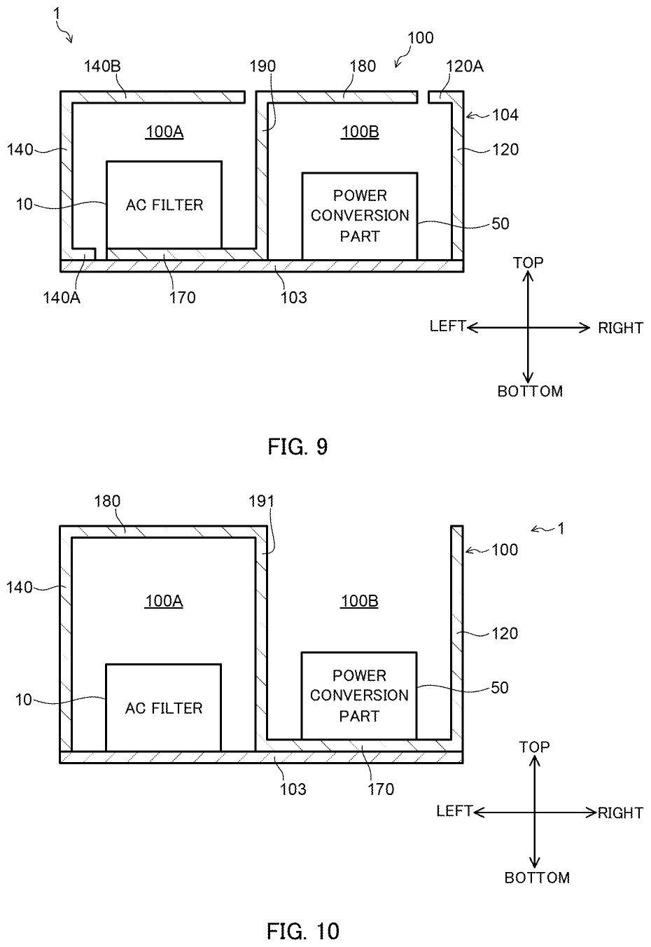

For example, as illustrated in FIG. 9, bottom wall 170, isolation wall 190 and top wall 180, and each side wall may not be connected to each other. Power conversion apparatus 1 illustrated in FIG. 9 includes housing 100, left side wall 140, right side wall 120, cooling part 103 and the like. Housing 100 includes isolation wall 190, bottom wall 170, top wall 180, a rear side wall and a front side wall. In addition, cooling part 103 has the same configuration as that of the present embodiment. Note that since FIG. 9 is a sectional view of power conversion apparatus 1 taken along a line parallel to the horizontal direction, illustration of the rear side wall and the front side wall is omitted.

As in the above-mentioned embodiment, bottom wall 170 is located in first region 100A (left side region) where AC filter 10 is disposed. As in the above-mentioned embodiment, top wall 180 is located in second region 100B (right side region) where power conversion part 50 and the like are disposed. Isolation wall 190 extends vertically, and connects the right end portion of bottom wall 170 and the left end portion of top wall 180. In addition, isolation wall 190 is also connected to the rear side wall and the front side wall.

Left side wall 140 includes first protrusion wall 140A protruding rightward from the lower end portion, and second protrusion wall 140B protruding rightward from the upper end portion.

First protrusion wall 140A constitutes a part of the bottom side wall of first region 100A. Bottom wall 170 is not provided in the entire range of first region 100A, and constitutes the bottom side wall of another part of first region 100A. That is, bottom wall 170 covers a part of first region 100A (AC filter 10). Bottom wall 170 and first protrusion wall 140A may be in contact with each other or may not be in contact with each other.

Second protrusion wall 140B constitutes a cover that covers first region 100A. Note that while a gap is formed between second protrusion wall 140B and isolation wall 190 in FIG. 9, the right end portion of second protrusion wall 140B is fixed to isolation wall 190 in practice. In addition, in the case where a gap is provided between second protrusion wall 140B and isolation wall 190, a cover may be additionally provided to fill the gap.

Right side wall 120 includes third protrusion wall 120A protruding from the upper end portion. Third protrusion wall 120A constitutes a portion of the top side wall of second region 100B. Top wall 180, which is not provided in the entire range of second region 100B, constitutes another portion of the top side wall of second region 100B. That is, top wall 180 constitutes a portion of the top side wall of second region 100B.

Note that while a gap is formed between third protrusion wall 120A and top wall 180 in FIG. 9, top wall 180 is fixed to the left end portion of third protrusion wall 120A in practice. In addition, in the case where a gap is provided between top wall 180 and third protrusion wall 120A, a cover may be additionally provided to fill the gap.

In addition, first protrusion wall 140A of left side wall 140, bottom wall 170 and right side wall 120 are disposed in cooling part 103.

Even with this configuration, isolation wall 190 can isolate first region 100A and second region 100B from each other without forming a gap, and thus propagation of noise generated in second region 100B to first region 100A can be suppressed.

In addition, while bottom wall 170 is located on the first region 100A side and top wall 180 is located on the second region 100B side in housing 100 in the present embodiment, the present disclosure is not limited to this. For example, it is possible to adopt a configuration in which bottom wall 170 is located on the second region 100B side (right side region) and top wall 180 is located on the first region 100A side (left side region) as illustrated in FIG. 10.

In this configuration, power conversion apparatus 1 includes housing 100, cooling part 103 and the like. Housing 100 includes left side wall 140, right side wall 120, isolation wall 191, bottom wall 170, top wall 180, a rear side wall, and a front side wall. As in the above-mentioned embodiment, left side wall 140, right side wall 120, the rear side wall and the front side wall constitute the four side walls of housing 100. Note that FIG. 10 is a sectional view of power conversion apparatus 1 taken along a line parallel to the horizontal direction, and therefore illustration of the rear side wall and the front side wall is omitted.

Top wall 180 extends rightward from the upper end portion of left side wall 140. Bottom wall 170 is disposed on the upper side of cooling part 103 and extends leftward from the lower end portion of right side wall 120. Isolation wall 191 connecting the left end portion of top wall 180 and the left end portion of bottom wall 170 is provided. The rear side wall and the front side wall are connected to left side wall 140, right side wall 120, isolation wall 191, top wall 180 and bottom wall 170.

Even with this configuration, first region 100A and second region 100B can be isolated from each other using isolation wall 191 without forming a gap, and thus propagation of noise generated in second region 100B to first region 100A can be suppressed.

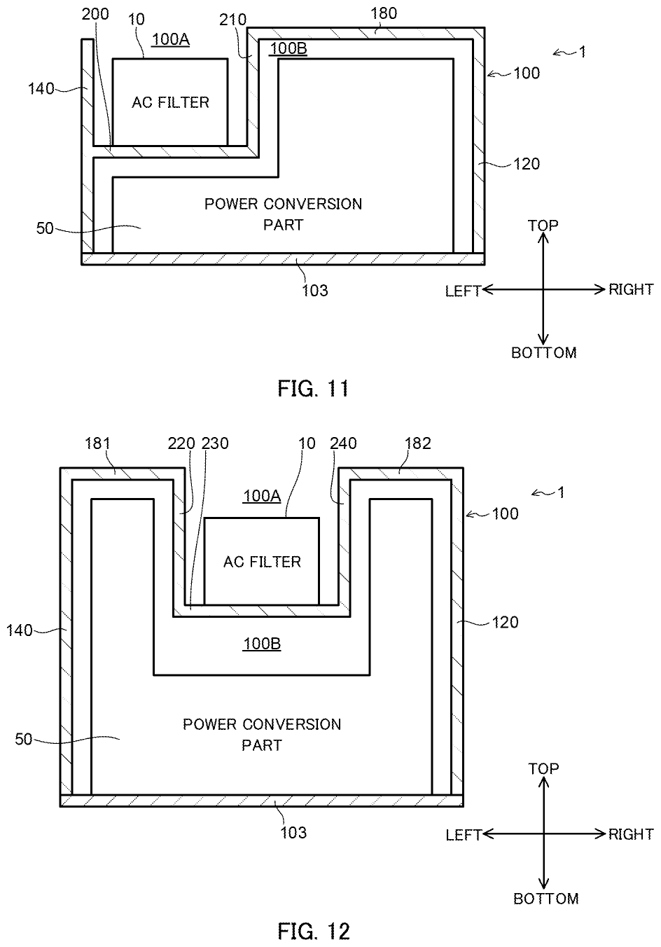

In addition, while cooling part 103 is disposed under bottom wall 170 of first region 100A where AC filter 10 is disposed in the present embodiment, the present disclosure is not limited to this. For example, as illustrated in FIG. 11 and FIG. 12, second region 100B where power conversion part 50 and the like are disposed may be located under intermediate wall 200, which is the bottom wall of first region 100A.

Power conversion apparatus 1 illustrated in FIG. 11 includes housing 100, cooling part 103 and the like. Housing 100 includes left side wall 140, right side wall 120, a front side wall and a rear side wall not illustrated in the drawing, intermediate wall 200, isolation wall 210, and top wall 180. Left side wall 140, right side wall 120, the front side wall and the rear side wall are vertically extending walls disposed on the upper side of cooling part 103, and constitute the four side walls of housing 100.

Intermediate wall 200 extends rightward from a center portion of left side wall 140 in the vertical direction. More specifically, intermediate wall 200 extends to near the center portion of housing 100 in the horizontal direction. Note that intermediate wall 200 is connected also to the front side wall and the rear side wall.

Isolation wall 210 extends vertically from the right end portion of intermediate wall 200 and is connected to top wall 180. Top wall 180 connects the upper end portion of isolation wall 210 and the upper end portion of right side wall 120. Note that top wall 180 is connected also to the front side wall and the rear side wall.

In this configuration, AC filter 10 is disposed in first region 100A surrounded by the top side portion of left side wall 140, intermediate wall 200 and isolation wall 210. Power conversion part 50 and the like are disposed in the region other than first region 100A, i.e., in second region 100B surrounded by the bottom side portion of left side wall 140, intermediate wall 200, isolation wall 210, top wall 180 and right side wall 120.

Even with this configuration, since intermediate wall 200, isolation wall 210 and top wall 180 are constituted integrally with each other, first region 100A and second region 100B are isolated from each other, and thus propagation of noise generated in second region 100B to first region 100A can be suppressed.

In addition, power conversion apparatus 1 illustrated in FIG. 12 includes housing 100, cooling part 103 and the like. Housing 100 includes left side wall 140, first top wall 181, left isolation wall 220, intermediate wall 230, right isolation wall 240, second top wall 182, right side wall 120, and a front side wall and a rear side wall not illustrated in the drawing. Left side wall 140, right side wall 120, the front side wall and the rear side wall are vertically extending walls disposed on the upper side of cooling part 103, and constitute the four side walls of housing 100.

First top wall 181 extends rightward from the upper end portion of left side wall 140. Left isolation wall 220 extends downward from the right end portion of first top wall 181.

Intermediate wall 230 extends rightward from the lower end portion of left isolation wall 220. Right isolation wall 240 extends upward from the right end portion of intermediate wall 230, and is connected to second top wall 182. Second top wall 182 is connected to the upper end portion of right side wall 120. In addition, first top wall 181, left isolation wall 220, intermediate wall 230, right isolation wall 240 and second top wall 182 are connected also to the front side wall and the rear side wall.

In this configuration, AC filter 10 is disposed in first region 100A surrounded by left isolation wall 220, intermediate wall 230 and right isolation wall 240. Power conversion part 50 and the like are disposed in the region other than first region 100A, i.e., in second region 100B surrounded by left side wall 140, first top wall 181, left isolation wall 220, intermediate wall 230, right isolation wall 240, second top wall 182 and right side wall 120.

Even with this configuration, since first top wall 181, left isolation wall 220, intermediate wall 230, right isolation wall 240 and second top wall 182 are constituted integrally with each other, first region 100A and second region 100B are isolated from each other, and thus propagation of noise generated in second region 100B to first region 100A can be suppressed.

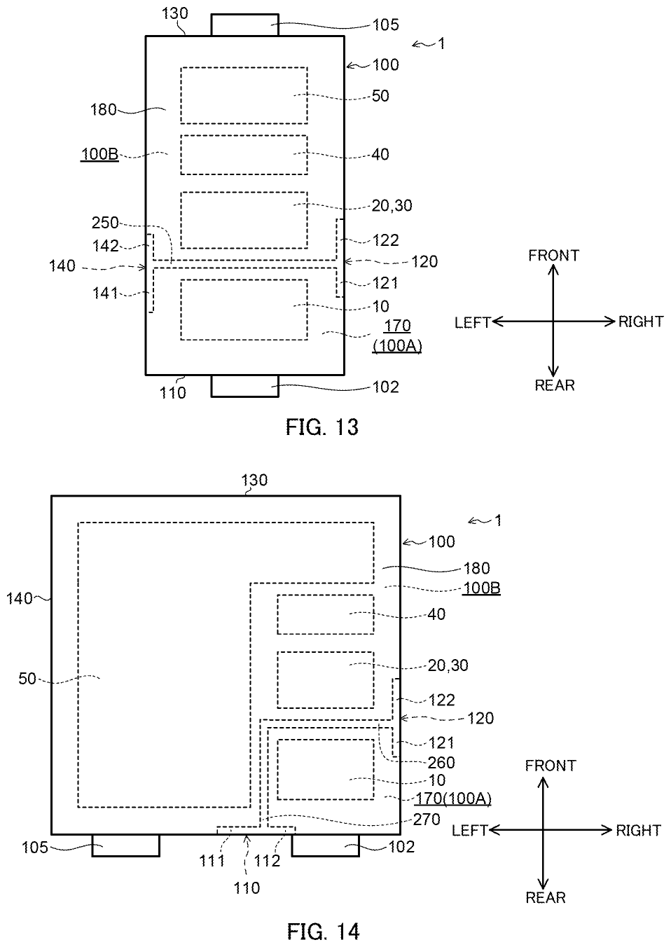

In addition, while first region 100A where AC filter 10 is disposed is located at the left rear part in housing 100 in the present embodiment, the present disclosure is not limited to this. For example, as illustrated in FIG. 13, first region 100A may be located in a rear part of housing 100.

Housing 100 in this configuration includes rear side wall 110, right side wall 120, front side wall 130, left side wall 140, bottom wall 170, top wall 180, and isolation wall 250. Rear side wall 110, right side wall 120, front side wall 130 and left side wall 140 are vertically extending walls. Note that housing 100 is disposed on the upper side of a cooling part not illustrated in the drawing as in the above-mentioned embodiment.

Isolation wall 250 is a wall that connects a rear side portion of right side wall 120 and a rear side portion of left side wall 140. Note that in the following description, a portion of right side wall 120 on the rear side of the rear side portion is referred to as rear side portion 121 of right side wall 120, and a portion on the front side of that portion is referred to as front side portion 122 of right side wall 120. In addition, a portion of left side wall 140 on the rear side of the rear side portion is referred to as rear side portion 141 of left side wall 140, and a portion on the front side of that portion is referred to as front side portion 142 of left side wall 140. In addition, while right side wall 120 and left side wall 140 extend in the entire front-rear direction of the housing 100, FIG. 13 illustrates only regions around the portions where they are connected to isolation wall 250 for the sake of clarity of the drawing. In addition, it suffices that right side wall 120 and left side wall 140 are provided at least in the proximity of portions where they are connected to isolation wall 250.

Bottom wall 170 connects the lower end portion of isolation wall 250 and the lower end portion of rear side wall 110. Bottom wall 170 is connected also to the lower end portion of each of rear side portion 121 of right side wall 120, and rear side portion 141 of left side wall 140.

Top wall 180 connects the upper end portion of isolation wall 250 and the upper end portion of front side wall 130. Top wall 180 is connected also to the upper end portion of each of front side portion 122 of right side wall 120, and front side portion 142 of left side wall 140.

In this configuration, AC filter 10 is disposed in first region 100A surrounded by rear side wall 110, bottom wall 170, isolation wall 250, rear side portion 141 of left side wall 140, and rear side portion 121 of right side wall 120. Note that top wall 180 is not disposed in a portion corresponding to first region 100A.

Inrush current prevention part 20, rectification part 30, capacitor 40 and power conversion part 50 are disposed in the region other than first region 100A, i.e., in second region 100B surrounded by isolation wall 250, top wall 180, front side wall 130, front side portion 142 of left side wall 140, and front side portion 122 of right side wall 120. Note that bottom wall 170 is not disposed in a portion corresponding to second region 100B. In addition, in front side wall 130, output part 105 where the output power of power conversion part 50 is output is provided.

In the configuration illustrated in FIG. 13, inrush current prevention part 20, rectification part 30, capacitor 40 and power conversion part 50 are arranged in the front-rear direction.

Even with this configuration, since top wall 180, isolation wall 250 and bottom wall 170 are constituted integrally with each other, first region 100A and second region 100B are isolated from each other, and thus propagation of noise generated in second region 100B to first region 100A can be suppressed.

In addition, with isolation wall 250, right side wall 120 and left side wall 140 constituted integrally with each other, first region 100A and second region 100B are isolated from each other, and propagation of noise generated in second region 100B to first region 100A can be suppressed.

In addition, as illustrated in FIG. 14, first region 100A may be located in a right rear part of housing 100. In this configuration, housing 100 includes rear side wall 110, right side wall 120, front side wall 130, left side wall 140, bottom wall 170, top wall 180, first isolation wall 260, and second isolation wall 270. Rear side wall 110, right side wall 120, front side wall 130 and left side wall 140 are vertically extending walls. Note that housing 100 is disposed on the upper side of a cooling part not illustrated as in the above-mentioned embodiment.

First isolation wall 260 is a wall that extends leftward from a rear side portion of right side wall 120, and is connected to second isolation wall 270. Note that in the following description, a portion of right side wall 120 on the rear side of the rear side portion is referred to as rear side portion 121 of right side wall 120, and a portion on the front side of that portion is referred to as front side portion 122 of right side wall 120.

Second isolation wall 270 is a wall that extends upward from a right side portion of rear side wall 110 and is connected to first isolation wall 260. Note that in the following description, a portion on the left side of the right side portion of rear side wall 110 is referred to as left side portion 111 of rear side wall 110, and a portion on the right side of that portion is referred to as right side portion 112 of rear side wall 110. In addition, while right side wall 120 extends in the entire front-rear direction of housing 100, FIG. 14 illustrates only a region around the portion where it is connected to first isolation wall 260 for the sake of clarity of the drawing. In addition, it suffices that right side wall 120 is provided at least in the proximity of a portion where it is connected to first isolation wall 260. In addition, while rear side wall 110 extends in the entire horizontal direction of housing 100, FIG. 14 illustrates only a region around the portion where it is connected to second isolation wall 270 for the sake of clarity of the drawing. In addition, it suffices that rear side wall 110 is provided at least in the proximity of a portion where it is connected to second isolation wall 270.

Bottom wall 170 connects the lower end portion of first isolation wall 260, the lower end portion of second isolation wall 270, the lower end portion of right side portion 112 of rear side wall 110, and the lower end portion of rear side portion 121 of right side wall 120.

Top wall 180 connects the upper end portion of first isolation wall 260, the upper end portion of second isolation wall 270, left side portion 111 of rear side wall 110, and front side portion 122 of right side wall 120. Top wall 180 is connected also to the upper end portion of front side wall 130 and the upper end portion of left side wall 140.

In this configuration, AC filter 10 is disposed in first region 100A surrounded by first isolation wall 260, second isolation wall 270, right side portion 112 of rear side wall 110, and rear side portion 121 of right side wall 120. Note that top wall 180 is not disposed in a portion corresponding to first region 100A. In addition, the above-described input part 102 is provided in right side portion 112 in rear wall 110.

Inrush current prevention part 20, rectification part 30, capacitor 40 and power conversion part 50 are disposed in the region other than first region 100A, i.e., in second region 100B surrounded by first isolation wall 260, second isolation wall 270, left side portion 111 of rear side wall 110, front side portion 122 of right side wall 120, front side wall 130 and left side wall 140. Note that bottom wall 170 is not disposed in a portion corresponding to second region 100B. In addition, the above-described output part 105 is provided in left side portion 111 of rear wall 110.

In the configuration illustrated in FIG. 14, inrush current prevention part 20, rectification part 30, capacitor 40 and a portion of power conversion part 50 are disposed in a right portion in second region 100B. The other portion of power conversion part 50 is disposed in a left portion in second region 100B.

Even with this configuration, since top wall 180, first isolation wall 260, second isolation wall 270 and bottom wall 170 are constituted integrally with each other, first region 100A and second region 100B are isolated from each other, and thus propagation of noise generated in second region 100B to first region 100A can be suppressed.

In addition, with first isolation wall 260, second isolation wall 270, right side wall 120 and rear side wall 110 constituted integrally with each other, first region 100A and second region 100B are isolated from each other, and propagation of noise generated in second region 100B to first region 100A can be suppressed.

The above-mentioned embodiments are merely examples of embodiments in implementing the present disclosure, and the technical scope of the present disclosure should not be construed as limited by them. In other words, the present disclosure can be implemented in various forms without deviating from its gist or its main features.

This application is entitled to and claims the benefit of Japanese Patent Application No. 2018-173556 filed on Sep. 18, 2018, the disclosure each of which including the specification, drawings and abstract is incorporated herein by reference in its entirety.

### INDUSTRIAL APPLICABILITY

With a simple configuration, the power conversion apparatus of the present disclosure is useful as a power conversion apparatus that can suppress propagation of noise to an AC filter.

### REFERENCE SIGNS LIST

1 Power conversion apparatus
2 External AC power source
3 Battery
10 AC filter
11 Substrate
20 Inrush current prevention part
30 Rectification part
40 Capacitor
50 Power conversion part
60 Circuit board
61 Fixing part
100 Housing
100A First region
100B Second region
101 Cover
102 Input part
102A First part
102B Second part
102C Third part
103 Cooling part
103A Fin
104 Fastening part
105 Output part
110 Rear side wall
111 Left side portion
112 Right side portion
113 Portion
120 Right side wall
130 Front side wall
140 Left side wall
141 Rear side portion
142 Front side portion
143 Portion
150 First isolation wall
151 First wall part
152 Second wall part
153 Third wall part
154 Fourth wall part
155 Fifth wall part
156 Sixth wall part
160 Second isolation wall
161 Seventh wall part
162 Eighth wall part
163 Ninth wall part
164 Tenth wall part
170 Bottom wall
180 Top wall

1. A power conversion apparatus configured to perform power conversion of AC power supplied from an AC power source into DC power, the power conversion apparatus comprising:
a power conversion part configured to perform power conversion through switching of a switching device;
an AC filter provided on a power line between the AC power source and the power conversion part; and
an isolation member configured to isolate the AC filter and the power conversion part from each other, the isolation member being conductive,
wherein the isolation member includes:
a first surface that constitutes at least a part of a first predetermined surface of a housing part configured to house the power conversion part, the first surface being configured to cover at least a part of the power conversion part on a first predetermined surface side,
a second surface configured to cover at least a part of one surface of the AC filter disposed outside the housing part, and
a third surface configured to connect the first surface and the second surface, and
wherein the first surface, the second surface and the third surface are integrally molded with each other so as to be conductive.

2. The power conversion apparatus according to claim 1,
wherein the isolation member further includes a fourth surface configured to cover at least a part of a surface of the AC filter different from the one surface, and
wherein the fourth surface and the third surface are integrally molded with each other so as to be conductive.

3. The power conversion apparatus according to claim 2, further comprising an input part where the AC power is input, the input part being disposed in the fourth surface.

4. The power conversion apparatus according to claim 3,
wherein the input part is connected to the AC filter through a connecting part, and
wherein the third surface is disposed along the input part, the AC filter, and the connecting part, and is configured to isolate the power conversion part and the AC filter from each other.

5. The power conversion apparatus according to claim 1,
wherein the isolation member further includes a fifth surface that constitutes at least a part of a second predetermined surface of the housing part, the second predetermined surface being different from the first predetermined surface, and
wherein the fifth surface and the third surface are integrally molded with each other so as to be conductive.

6. The power conversion apparatus according to claim 1, wherein the third surface includes a portion protruding to a region on an AC filter side.

7. The power conversion apparatus according to claim 1, further comprising a cooling part including a fin configured to use air to cool the power conversion part.
